(19) United States
(12) Patent Application Publication
(10) Pub. No.: US 2025/0151628 A1
(43) Pub. Date: May 8, 2025

(54) Mn-Sb COMPOUNDS FOR MAGNETIC RANDOM ACCESS MEMORY FREE LAYER

(71) Applicants: Samsung Electronics Co., Ltd., Gyeonggi-do (KR); INTERNATIONAL BUSINESS MACHINES CORPORATION, Armonk, NY (US)

(72) Inventors: Roman Chepulskyy, Santa Clara, CA (US); Dmytro Apalkov, San Jose, CA (US); FNU Ikhtiar, San Jose, CA (US); Jaewoo Jeong, Los Altos, CA (US); Chirag Garg, San Jose, CA (US); Panagiotis Charilaos Filippou, San Jose, CA (US); See-Hun Yang, San Jose, CA (US); Mahesh G. Samant, San Jose, CA (US)

(21) Appl. No.: 18/500,692

(22) Filed: Nov. 2, 2023

(51) Int. Cl. H10N 50/10; H10B 61/00; H10N 50/01; H10N 50/85

(52) U.S. Cl. CPC H10N 50/10; H10B 61/00; H10N 50/01; H10N 50/85

(57) ABSTRACT

Methods and apparatuses are provided for MRAM devices including an Mn—Sb compound free layer MTJ. A device includes an MTJ including a reference layer, a tunneling barrier layer, and a top free layer, wherein the tunneling barrier layer is formed on the reference layer, the top free layer is formed over the tunneling barrier layer, and the top free layer includes an Mn—Sb compound; and a capping layer formed over the top free layer of the MTJ.

### TECHNICAL FIELD

The disclosure relates generally to the field of magnetic random access memory (MRAM), and more particularly, to an MRAM device including a magnetic tunneling junction (MTJ) having a free layer formed using an Mn—Sb compound.

### BACKGROUND

Magnetic memories such as MRAMs store information utilizing magnetic materials as an information storage medium. For example, an MTJ may be used in an MRAM, such as a spin transfer torque MRAM (STT-MRAM). The MTJ typically includes a reference layer, a free layer, and a tunneling barrier layer between the reference and free layers. The reference and free layers are magnetic. The magnetic moment of the reference layer is generally fixed, or pinned, in a particular direction. The free layer has a changeable magnetic moment and is used to store information. A bottom contact below the MTJ and a top contact on the MTJ are used to drive current through the MTJ in a current-perpendicular-to-plane (CPP) direction in an STT-MRAM. In case of MTJs with positive tunnel magnetoresistance (TMR), when a sufficient current is driven in one direction perpendicular-to-plane (e.g., top to bottom), the free layer magnetic moment switches to be parallel to that of the reference layer. When a sufficient current is driven in the opposite direction (e.g., bottom to top), the free layer magnetic moment switches to be antiparallel to that of the reference layer. Different magnetic configurations correspond to different magnetoresistances and thus different logical states (e.g. a logical “0” and a logical “1”) of the MTJ.

Because MRAM has advantages of lower power consumption and better scalability, it can replace low-density dynamic random access memory (DRAM) and static random access memory (SRAM), e.g., in mobile and storage devices.

However, in MRAM, smaller switching currents are needed when the magnetic layers have magnetization perpendicular to a film surface, i.e., have perpendicular magnetic anisotropy (PMA), than for in-plane magnetized MTJs.

Additionally, lower switching currents are needed for low-power MRAM products that can operate at a nanosecond regime (e.g., 2-50 ns).

### SUMMARY

Accordingly, an aspect of the disclosure is to provide an apparatus and method for obtaining lower switching current in MTJ devices.

Another aspect of the disclosure is to provide an MTJ device including a free layer formed using an Mn—Sb compound having PMA and low saturation magnetization (Mₛ).

In accordance with an aspect of the disclosure, a device is provided, which includes an MTJ including a reference layer, a tunneling barrier layer, and a top free layer, wherein the tunneling barrier layer is formed on the reference layer, the top free layer is formed over the tunneling barrier layer, and the top free layer includes an Mn—Sb compound; and a capping layer formed over the top free layer of the MTJ.

In accordance with another aspect of the disclosure, a device is provided, which includes an MTJ including a reference layer, a tunneling barrier layer, and a bottom free layer, wherein the tunneling barrier layer is formed over the bottom free layer, the reference layer is formed on the tunneling barrier layer, and the bottom free layer includes an Mn—Sb compound; and a capping layer formed over the reference layer of the MTJ.

In accordance with another aspect of the disclosure, a method is provided, which includes forming an MTJ including a reference layer, a tunneling barrier layer, and a free layer, wherein the free layer includes an Mn—Sb compound; and forming a capping layer over the MTJ.

In accordance with another aspect of the disclosure, an electronic device is provided, which includes a processor; and a memory device including an MTJ including a reference layer, a tunneling barrier layer, and a free layer, wherein the free layer includes an Mn—Sb compound; and a capping layer formed over the free layer of the MTJ.

### BRIEF DESCRIPTION OF THE DRAWING

The above and other aspects, features, and advantages of the disclosure will be more apparent from the following detailed description taken in conjunction with the accompanying drawings, in which:

FIG. 1 illustrates a conventional memory cell/unit of an MRAM product including an MTJ;

FIG. 2A illustrates a memory cell/unit of an MRAM product including an MTJ, according to an embodiment;

FIG. 2B illustrates a memory cell/unit of an MRAM product including an MTJ, according to an embodiment;

FIG. 2C illustrates a memory cell/unit of an MRAM product including an MTJ, according to an embodiment;

FIG. 3A illustrates a memory cell/unit of an MRAM product including an MTJ, according to an embodiment;

FIG. 3B illustrates a memory cell/unit of an MRAM product including an MTJ, according to an embodiment;

FIG. 3C illustrates a memory cell/unit of an MRAM product including an MTJ, according to an embodiment;

FIG. 4 illustrates a memory cell/unit of an MRAM product including a spin-orbit torque (SOT) line, according to an embodiment;

FIG. 5 illustrates a memory cell/unit of an MRAM product including an SOT line, according to an embodiment;

FIG. 6 illustrates an electronic device, according to an embodiment;

FIG. 7 is a flowchart illustrating a method of forming a memory cell/unit of an MRAM product including an Mn—Sb compound top free layer MTJ, according to an embodiment; and

FIG. 8 is a flowchart illustrating a method of forming a memory cell/unit of an MRAM product including an Mn—Sb compound bottom free layer MTJ, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components, and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Further, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments.

Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. The dimensions of some of the elements may be exaggerated relative to other elements for clarity. For example, the dimensions of layers and regions may be exaggerated for clarity of illustration.

Further, if considered appropriate, reference numerals may be repeated among the figures to indicate corresponding and/or analogous elements. That is, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise.

As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

When an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, e.g., but not limited to, an IC, system on-a-chip (SoC), an assembly, etc.

Embodiments of the disclosure relate to MTJ devices and methods of manufacturing MTJ devices.

Embodiments relate to magnetic junctions usable in magnetic devices, such as magnetic memories, and the devices using such magnetic junctions. The magnetic memories may include STT-MRAMs, SOT memories, and may be used in electronic devices employing nonvolatile memory. Other devices including magnetic junctions, particularly, STT or SOT programmable magnetic junctions, include but are not limited to logic, neuromorphic computing cells, and other devices. Electronic devices include but are not limited to cellular phones, smart phones, tables, laptops and other portable and non-portable computing devices.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), etc. Semiconductor doping is the modification of electrical properties by doping, e.g., transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the structures that make up an IC device, lithography and etch pattern transfer steps are repeated multiple times. Each pattern being printed on the wafer is aligned to the previously formed patterns and slowly the conductors, insulators and selectively doped regions are built up to form the final device.

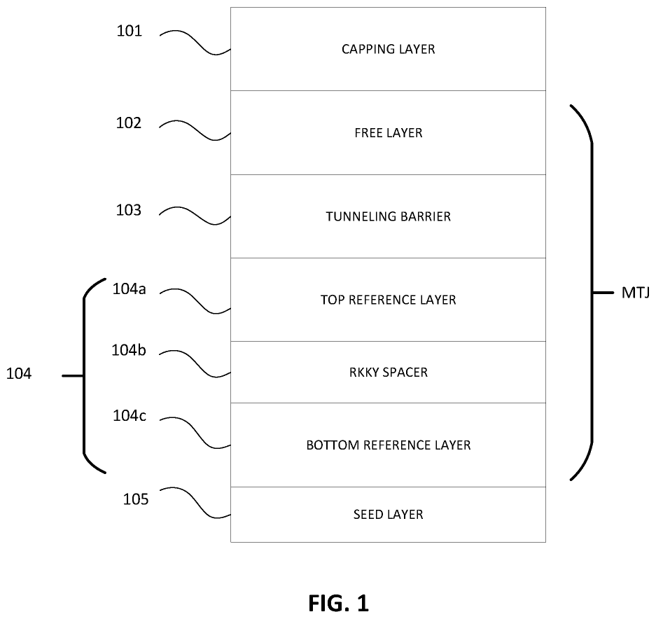

FIG. 1 illustrates a conventional memory cell/unit of an MRAM product including an MTJ.

Referring to FIG. 1, the memory cell/unit of the MRAM product includes a seed (or substrate) layer 105, a reference layer 104, a tunneling barrier layer 103, a free layer 102, and a capping layer 101. The reference layer includes a top reference layer 104a, a Ruderman-Kittel-Kasuya-Yosida (RKKY) spacer 104b, and a bottom reference layer 104c.

The reference layer 104, the tunneling barrier layer 103, and the free layer 102 make up the MTJ.

However, the free layer 102 generally consists of high Mₛ, Fe-based materials (e.g., Fe, CoFeB, etc.), and therefore, is unsuitable for low-power MRAM products with PMA.

Accordingly, an aspect of the disclosure is to provide a new free layer including Mn—Sb compounds having PMA and low Mₛ.

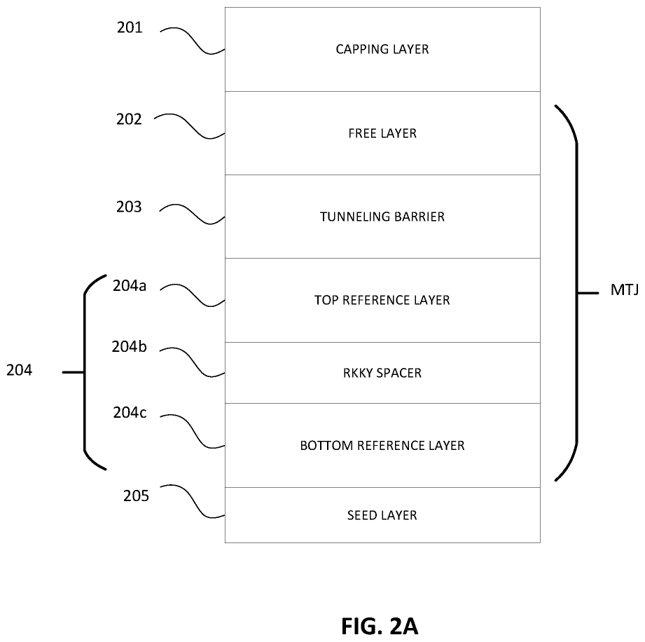

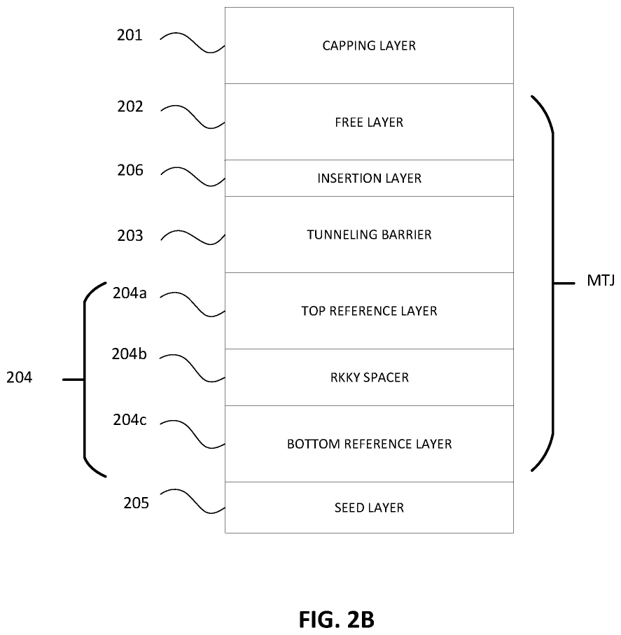

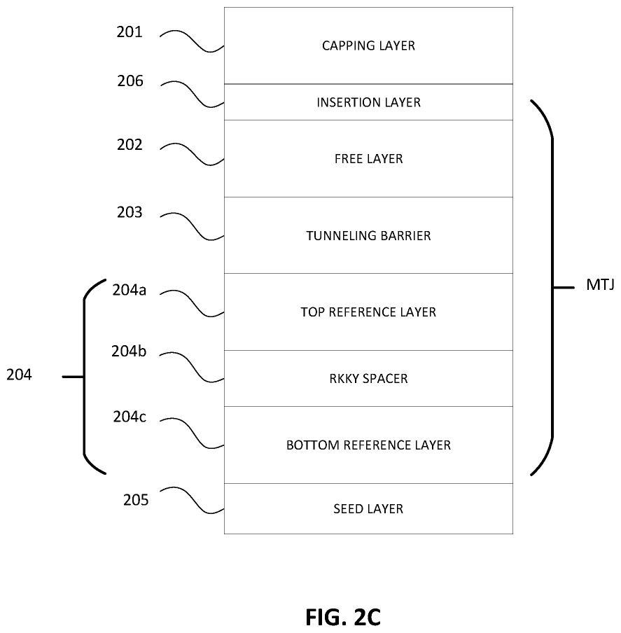

FIG. 2A illustrates a memory cell/unit of MRAM product including an MTJ, according to an embodiment. The memory cell/unit of MRAM product illustrated in FIG. 2A may also be referred to as a top free layer MTJ.

Referring to FIG. 2A, the memory cell/unit of the MRAM product includes a seed (or substrate) layer 205, a reference layer 204, a tunneling barrier layer 203, a free layer (or top free layer) 202, and a capping layer (or oxide layer) 201. The reference layer 204 includes a top reference layer 204a, an RKKY spacer 204b, and a bottom reference layer 204c. For example, the top reference layer 204a, and the bottom reference layer 204c may be a multilayered structure including one or more of Co, Ni, Fe, B, CoFeB, Pt, Pd, Ta, W, and Mo.

The seed layer 205 may include Pt, Ru, Ir, Ta, CoFeB, CoFeBTa, TaB, TiN or TaN. The seed layer 205 may also include a combination of at least two of the above-mentioned materials that form a bilayer structure or a multilayered structure.

The capping layer 201 may include an Oxide such as MgO, Mg—Al-Ox, Zr-Ox, Hf-Ox, Al-Ox, Ta-Ox, or Ca-Ox, a metallic element/alloy such as Ta, Mo, W, Ru, CoFeB, or TaB, and/or a nitride such as TiN, TaN, ScN, or VN. The capping layer 201 may also include a combination of at least two of the above-mentioned materials that form a bilayer structure or a multilayered structure.

The reference layer 204, the tunneling barrier layer 203, and the free layer 202 make up the MTJ.

The tunneling barrier layer 203 may include MgO. The tunneling barrier layer 203 may include MgAl₂O₄ and can be used as a tunnel barrier whose lattice spacing can be tuned (engineered) by controlling the Mg—Al composition to result in better lattice matching with the Heusler compounds. For example, the composition of the tunneling barrier layer 203 can be represented as Mg_{1-z}Al_{2+(2/3)z}O₄, where −0.5<z<0.5).

Different from the memory cell/unit of the MRAM product illustrated in FIG. 1, the free layer 202 includes an Mn—Sb compound having PMA and low Mₛ, and therefore, is suitable for low-power MRAM products with PMA. The magnetization of the free layer 202 including the Mn—Sb compound is substantially perpendicular to the tunneling barrier layer 203.

More specifically, the free layer 202, which is 0.5-10 nm thick, may include Mn₂Sb in C38 crystal structure, Mn₃Sb in D0₂₂ crystal structure, or MnₓSb, where x=1.5-3.

For example, Mn₃Sb has high PMA, has a D0₂₂ crystal structure similar to that observed for Mn₃Ge, and is a tetragonal Heusler compound, which is ferrimagnetic with a low moment, and provides TMR in MgO sandwiched structures.

Additionally, Mn—Sb compounds are compatible with current state-of-the-art MTJ technology and more preferable for scaling.

FIG. 2B illustrates a memory cell/unit of an MRAM product including an MTJ, according to an embodiment.

Referring to FIG. 2B, the memory cell/unit of the MRAM product includes a seed layer 205, a reference layer 204, a tunneling barrier layer 203, a free layer (or top free layer) 202, and a capping layer 201. The reference layer 204 includes a top reference layer 204a, an RKKY spacer 204b, and a bottom reference layer 204c, as described above with reference to FIG. 2A, and also includes an insertion layer 206 between the tunneling barrier layer 203 and the free layer 202.

The insertion layer 206, which may be 0.1-2 nm thick, may be made of Co, Fe, Ni, Ta, Mo, W, or Mn or a Co-containing alloy, an Fe-containing alloy, an Ni-containing alloy, or an Mn-containing alloy. The insertion layer 206 may include any one or a combination of at least two of the above-mentioned materials.

The insertion layer 206 provides a barrier for diffusion between the tunneling barrier layer 203 and the free layer 202. The insertion layer 206 may also provide higher TMR than that without one due to improved/higher spin polarization or improved/higher spin-filtering effect with the tunneling barrier layer 203. The insertion layer 206 may also be used to adjust/tune the strength of PMA and the total magnetic moment of the free layer 202.

FIG. 2C illustrates a memory cell/unit of an MRAM product including an MTJ, according to an embodiment.

Referring to FIG. 2C, the memory cell/unit of the MRAM product includes a seed layer 205, a reference layer 204, a tunneling barrier layer 203, a free layer (or top free layer) 202, and a capping layer 201. The reference layer 204 includes a top reference layer 204a, an RKKY spacer 204b, and a bottom reference layer 204c, as described above with reference to FIG. 2A, and also includes an insertion layer 206 between the free layer 202 and the capping layer 201.

The insertion layer 206, which may be 0.1-2 nm thick, may be made of Co, Fe, Ni, Ta, Mo, W, or Mn or a Co-containing alloy, an Fe-containing alloy, an Ni-containing alloy, or an Mn-containing alloy. The insertion layer 206 may include any one or a combination of at least two of the above-mentioned materials.

The insertion layer 206 provides a barrier for diffusion between the capping layer 201 and the free layer 202. The insertion layer 206 may also be used to adjust/tune the strength of PMA and the total magnetic moment of the free layer 202.

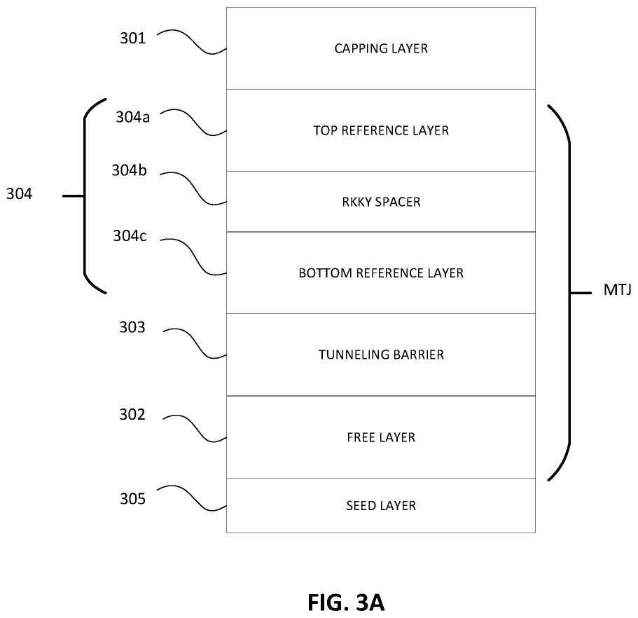

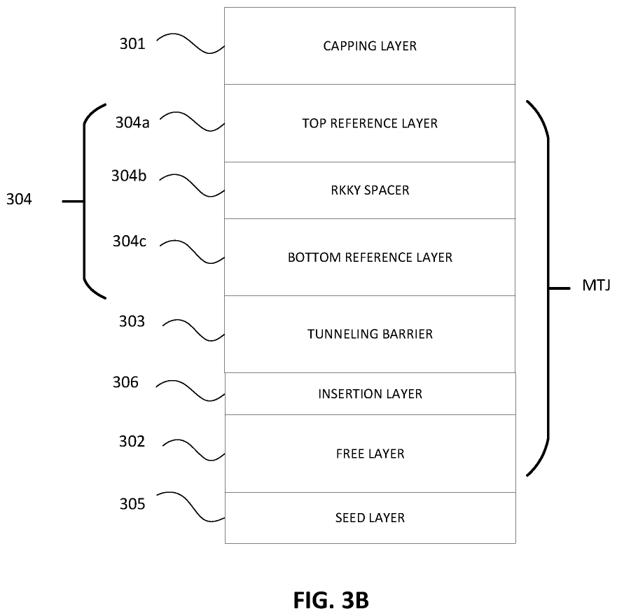

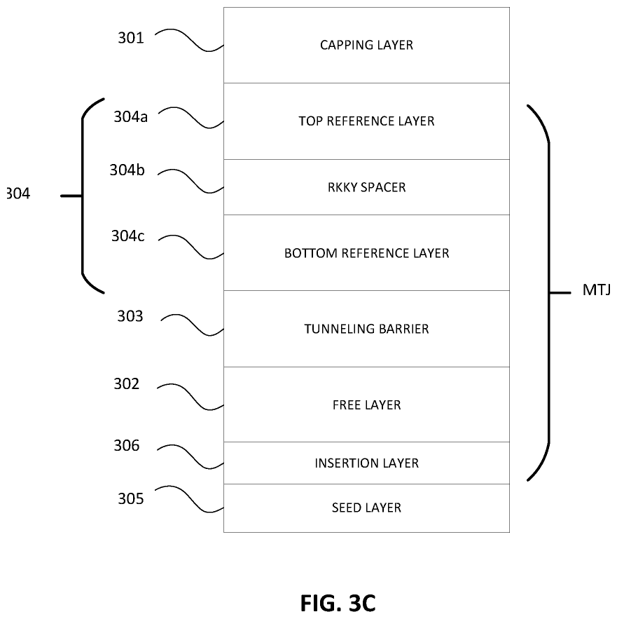

FIG. 3A illustrates a memory cell/unit of an MRAM product including an MTJ, according to an embodiment. The memory cell/unit of the MRAM product illustrated in FIG. 3A may also be referred to as a bottom free layer MTJ.

Referring to FIG. 3A, the memory cell/unit of the MRAM product includes a seed (or substrate) layer 305, a free layer (or bottom free layer) 302, a tunneling barrier layer 303, a reference layer 304, and a capping layer 301. The reference layer 304 includes a top reference layer 304a, an RKKY spacer 304b, and a bottom reference layer 304c.

The reference layer 304, the tunneling barrier layer 303, and the free layer 302 make up the MTJ.

Compared to the embodiment in FIG. 2A described above, the layers of the memory cell/unit of the MRAM product are essentially the same except for the seed layer 305 and the capping layer 301. That is, the reference layer 304, the tunneling barrier layer 303, and the free layer 302 are the same as the reference layer 204, the tunneling barrier layer 203, and the free layer 202, except for being formed in reverse so that the free layer 302 is at the bottom of the MTJ or below the tunneling barrier layer 303.

The seed layer 305 may include an oxide, such as MgO, Mg—Al-Ox, Zr-Ox, Hf-Ox, Al-Ox, Ta-Ox, or Ca-Ox, a nitride, such as ScN. VN, TaN, TiN, Mnx-N, or AlN, or B2-structure compounds/alloys, such as CoAl, NiAl, FeAl, CoGa, CoGe, or CoSn. The seed layer 305 may also include a combination of at least two of the above-described materials, e.g., a bilayer structure, such as oxide/metal, nitride/metal, nitride/oxide, etc.

The capping layer 301 may include Pt, Ru, Ir, Ta, CoFeB, CoFeBTa, TaB, TiN, or TaN. The capping layer 301 may include a combination of at least two of the above-mentioned materials that form a bilayer structure or a multilayered structure.

FIG. 3B illustrates a memory cell/unit of an MRAM product including an MTJ, according to an embodiment.

Referring to FIG. 3B, the memory cell/unit of the MRAM product includes a seed layer 305, a free layer (or bottom free layer) 302, a tunneling barrier layer 303, a reference layer 304, and a capping layer 301. The reference layer 304 includes a top reference layer 304a, an RKKY spacer 304b, and a bottom reference layer 304c, as described above with reference to FIG. 3A, and also includes an insertion layer 306 between the tunneling barrier layer 303 and the free layer 302.

The insertion layer 306, which may be 0.1-2 nm thick, may be made of Co, Fe, Ni, Ta, Mo, W, or Mn or a Co-containing alloy, an Fe-containing alloy, an Ni-containing alloy, or an Mn-containing alloy. The insertion layer 306 may include any one or a combination of at least two of the above-mentioned materials.

The insertion layer 306 provides a barrier for diffusion between the tunneling barrier layer 303 and the free layer 302. The insertion layer 306 may also provide higher TMR than that without one due to improved/higher spin polarization or improved/higher spin-filtering effect with the tunneling barrier layer 303. The insertion layer 306 may also be used to adjust/tune the strength of PMA and the total magnetic moment of the free layer 302.

FIG. 3C illustrates a memory cell/unit of an MRAM product including an MTJ, according to an embodiment.

Referring to FIG. 3C, the memory cell/unit of the MRAM product includes a seed layer 305, a free layer (or bottom free layer) 302, a tunneling barrier layer 303, a reference layer 304, and a capping layer 301. The reference layer 304 includes a top reference layer 304a, an RKKY spacer 304b, and a bottom reference layer 304c, as described above with reference to FIG. 3A, and also includes an insertion layer 306 between the free layer 302 and the seed layer 305.

The insertion layer 306, which may be 0.1-2 nm thick, may be made of Co, Fe, Ni, Ta, Mo. W. or Mn or a Co-containing alloy, an Fe-containing alloy, an Ni-containing alloy, or an Mn-containing alloy. The insertion layer 306 may include any one or a combination of at least two of the above-mentioned materials.

The insertion layer 306 provides a barrier for diffusion between the seed layer 305 and the free layer 302. The insertion layer 306 may also provide better free layer 302 growth on the seed layer 305 due to better lattice mismatch and/or wettability. The insertion layer 306 may also be used to adjust/tune the strength of PMA and the total magnetic moment of the free layer 302.

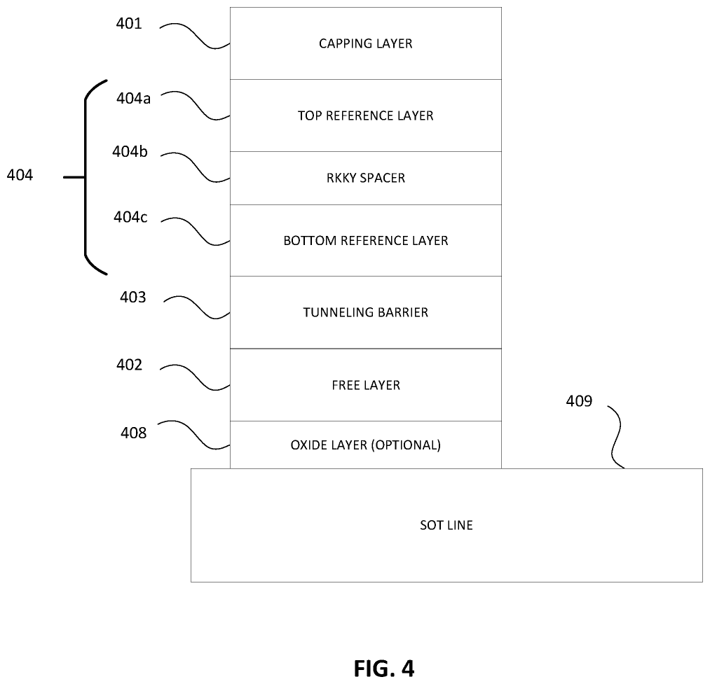

FIG. 4 illustrates a memory cell/unit of an MRAM product including an SOT line, according to an embodiment.

Referring to FIG. 4, the memory cell/unit of the MRAM product includes an SOT line 409, an oxide layer 408, a free layer 402, a tunneling barrier layer 403, a reference layer 404, and a capping layer 401. The reference 404 layer includes a top reference layer 404a, an RKKY spacer 404b, and a bottom reference layer 404c.

Notably, the layers of the memory cell/unit of the MRAM product in FIG. 4 are similar to that in FIG. 3A, as both memory cell/units of the MRAM products include a bottom free layer MTJ. Although the bottom free layer MTJ in FIG. 3A is formed over the seed layer 305, the bottom free layer MTJ in FIG. 4 is formed over the oxide layer 408 and the SOT line 409.

The SOT line 409 provides additional current-induced spin-orbit torque, which allows for fast and efficient manipulation of the magnetic state of the free layer 402 of the MTJ.

The SOT line 409 may include Ta, W, Pt, or Hf. The SOT line 409 may include alloys of 2 or more of W. Pt, Tb, Bi, Hf, Zr, Ag, Au, Si, Cu, Cr, V, and/or Mo (e.g., WHf). The SOT line 409 may also include multiple layers of the above-described materials, e.g., Au/Si layers.

The SOT line 409 may also include the above-described materials with oxidation at an interface, e.g., a W layer oxidized after deposition to increase resistivity and spin Hall angle (SHA).

The SOT line 409 may also include multilayer oxides of the above-described materials, e.g., W/Ox/W/Ox/W/Ox, where Ox is oxygen treatment.

The SOT line 409 may also include topological insulators, such as BiTe, BiSe, TIBiTe, TlBiSe, SbTeS, BiTeS, BiTeSe, GeSbTe, SnSbTe, GeBiTe, SnBiTe, BiSb, or BiSbSe.

The SOT line 409 may include IrO₂ and SrIrO₃.

The SOT line 409 may include heavy metal based anti-ferromagnet or ferrimagnet material, such as AₓB₁₋ₓ, where A=Ir. Pt. Pd, and Rh; B=Mn, Fe; and 0<x<1.

The oxide layer 408 is included to reduce shunting and improve SHA. The oxide layer 408 may have thickness of 0.4 nm-15 nm, and may include NiO, MgO, or AlO.

Although FIG. 4 illustrates the oxide layer 408 between the free layer 402 and the SOT line 409, the oxide layer 408 is optional and may be omitted.

Additionally, although FIG. 4 illustrates an MTJ stack similar that in FIG. 3A, the disclosure is not limited thereto. For example, an MTJ including an insertion layer, like insertion layer 306 illustrated in FIG. 3B or 3C, may also be formed over the oxide layer 408 and the SOT line 409.

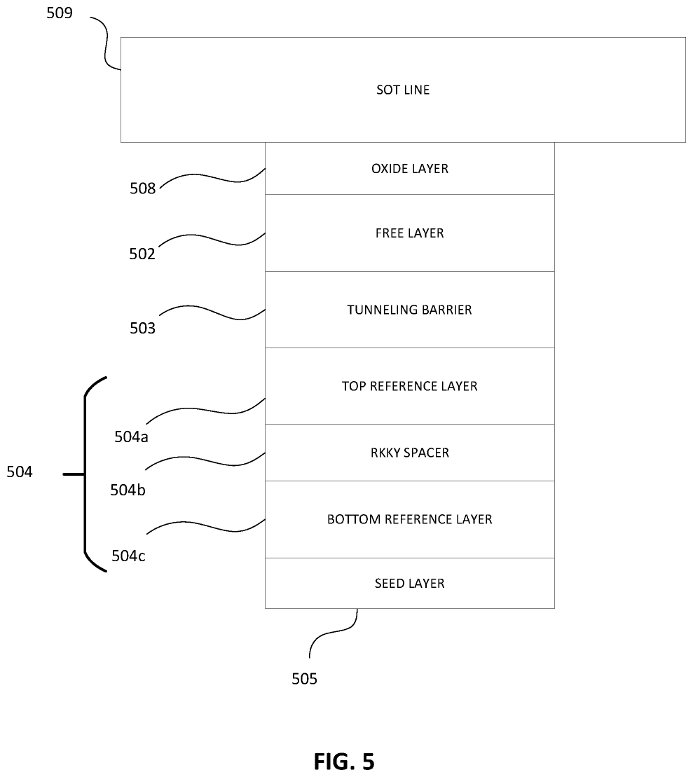

FIG. 5 illustrates a memory cell/unit of an MRAM product including an SOT line, according to an embodiment.

Referring to FIG. 5, the memory cell/unit of the MRAM product includes a seed layer 505, a reference layer 504, a tunneling barrier layer 503, a free layer 502, an oxide layer 508, and an SOT line 509. The reference layer 504 includes a top reference layer 504a, an RKKY spacer 504b, and a bottom reference layer 504c.

Notably, the layers of the memory cell/unit of the MRAM product in FIG. 5 are similar to that in FIG. 2A, as both memory cells/units of the MRAM products include a top free layer MTJ. Although the bottom free layer MTJ in FIG. 2A is formed under the capping layer 201, the top free layer MTJ in FIG. 5 is formed under the oxide layer 508 and the SOT line 509.

As described above, the SOT line 509 provides additional current-induced spin-orbit torque, which allows for fast and efficient manipulation of the magnetic state of the free layer 502 of the MTJ.

The SOT line 509 and the oxide layer 508 may be formed using the same materials as described in FIG. 4.

Although FIG. 5 illustrates the oxide layer 508 between the free layer 502 and the SOT line 509, the oxide layer 508 is optional and may be omitted.

Additionally, although FIG. 5 illustrates an MTJ stack similar that in FIG. 2A, the disclosure is not limited thereto. For example, an MTJ including an insertion layer, like insertion layer 206 illustrated in FIG. 2B or 2C, may also be formed below the oxide layer 508 and the SOT line 509.

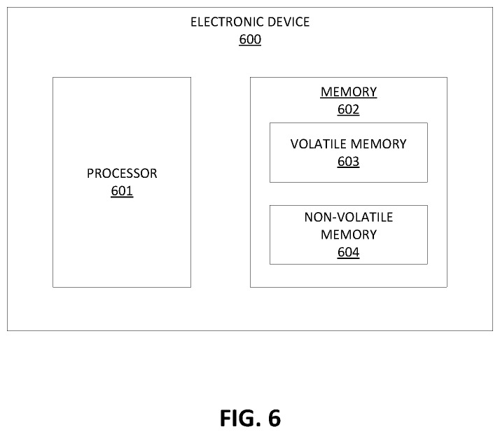

FIG. 6 illustrates an electronic device, according to an embodiment.

Referring to FIG. 6, an electronic device 600, e.g., a user equipment (UE) or a mobile terminal, includes a processor 601 and a memory 602. Although not illustrated in FIG. 6, dependent on the type of the electronic device 600, the electronic device 600 may include various additional components, such as an input device, a sound output device, a display device, an audio module, a sensor module, an interface, a haptic module, a camera module, a power management module, a battery, a communication module, a subscriber identification module (SIM), and/or an antenna module.

The processor 601 may execute, for example, software (e.g., a program) to control at least one other component (e.g., a hardware or a software component) of the electronic device 600, and may perform various data processing or computations. As at least part of the data processing or computations, the processor 601 may load a command or data received from another component in volatile memory 603, process the command or the data stored in the volatile memory 603, and store resulting data in non-volatile memory 604. The processor 601 may include a main processor (e.g., a central processing unit (CPU) or an application processor, and an auxiliary processor (e.g., a graphics processing unit (GPU), an image signal processor (ISP), a sensor hub processor, or a communication processor (CP)) that is operable independently from, or in conjunction with, the main processor.

The memory 602 may store various data used by at least one component (e.g., the processor 601) of the electronic device 600. The various data may include, for example, software (e.g., the program) and input data or output data for a command related thereto. The memory 630 may include the volatile memory 603 or the non-volatile memory 604. The non-volatile memory 604 includes a memory cell/unit of an MRAM product, e.g., as illustrated in FIGS. 2A, 2B, 2C, 3A, 3B, 3C, 4, and 5.

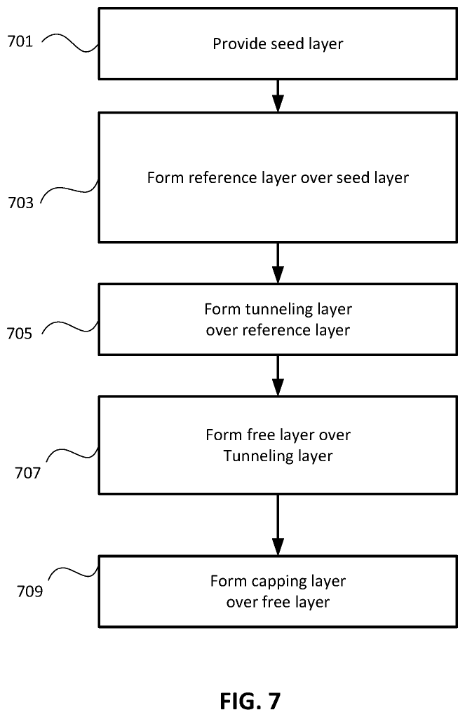

FIG. 7 is a flowchart illustrating a method of forming a memory cell/unit of an MRAM product including an Mn—Sb compound top free layer MTJ, according to an embodiment. For example, the method of FIG. 7 may be used to form the memory cell/unit of the MRAM product illustrated in FIG. 2A.

Referring to FIG. 7, in step 701, a seed layer is provided. The seed layer may include Pt, Ru, Ir, Ta, CoFeB, CoFeBTa, TaB, TiN, or TaN. The seed layer may also include a combination of at least two of the above-mentioned materials that form a bilayer structure or a multilayered structure.

In step 703, a reference layer is formed over the seed layer. As described above, the reference layer may include a top reference layer, an RKKY spacer, and a bottom reference layer.

In step 705, a tunneling barrier layer is formed over the reference layer. The tunneling barrier layer may include MgO. The tunneling barrier layer may include MgAl₂O₄ and can be used as a tunnel barrier whose lattice spacing can be tuned (engineered) by controlling the Mg—Al composition to result in better lattice matching with the Heusler compounds. For example, the composition of the tunneling barrier layer 203 can be represented as Mg_{1-z}Al_{2+(2/3)z}O₄, where −0.5<z<0.5).

In step 707, a free layer is formed over the tunneling barrier layer. The reference layer, the tunneling barrier layer, and the free layer make up the MTJ.

The free layer includes an Mn—Sb compound having PMA and low Mₛ, and therefore, is suitable for low-power MRAM products with PMA. The magnetization of the free layer including the Mn—Sb compound is substantially perpendicular to the tunneling barrier layer.

More specifically, the free layer may include Mn₂Sb in a C38 crystal structure, Mn₃Sb in a D0₂₂ crystal structure, or MnₓSb, where x=1.5-3. For example, the thickness of the free layer may be between 0.5-10 nm.

In step 709, a capping layer is formed over the free layer. The capping layer may include an Oxide such as MgO, Mg—Al-Ox, Zr-Ox, Hf-Ox, Al-Ox, Ta-Ox, or Ca-Ox, a metallic element/alloy such Ta, Mo, W, Ru, CoFeB, or TaB, and/or a nitride such as TiN, TaN, ScN, or VN. The capping layer 201 may include a combination of at least two of the above-mentioned materials that form a bilayer structure or a multilayered structure.

Alternatively, an insertion layer may be formed between the tunneling barrier layer and the free layer, e.g., as illustrated in FIG. 2B, or may be formed between the free layer and the capping layer, e.g., as illustrated in FIG. 2C. For example, insertion layer may include Co, Fe, Ni, Ta, Mo, W. or Mn or a Co-containing alloy, an Fe-containing alloy, an Ni-containing alloy, or an Mn-containing alloy. The insertion layer 206 may also include any one or a combination of at least two of the above-mentioned materials.

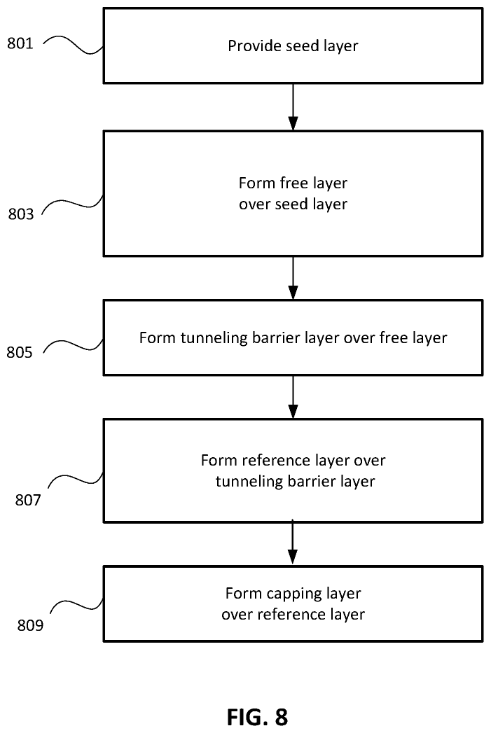

FIG. 8 is a flowchart illustrating a method of forming a memory cell/unit of an MRAM product including an Mn—Sb compound bottom free layer MTJ, according to an embodiment. Basically, the method in FIG. 8, aside from the initial seed layer, is a reverse of the method in FIG. 7. For example, the method of FIG. 8 may be used to form the memory cell/unit of the MRAM product illustrated in FIG. 3A.

Referring to FIG. 8, in step 801, a seed layer is provided. The seed layer 305 may include an oxide, such as MgO, Mg—Al-Ox, Zr-Ox, Hf-Ox, Al-Ox, Ta-Ox, or Ca-Ox, a nitride, such as ScN, VN, TaN, TiN, Mnx-N, or AlN, or B2-structure compounds/alloys, such as CoAl, NiAl, FeAl, CoGa, CoGe, or CoSn. The seed layer may include a combination of at least two of the above-described materials, e.g., a bilayer structure, such as oxide/metal, nitride/metal, nitride/oxide, etc.

In step 803, a free layer is formed over the seed layer. As described above, the free layer includes an Mn—Sb compound having PMA and low Mₛ, and therefore, is suitable for low-power MRAM products with PMA.

In step 805, a tunneling barrier layer, e.g., MgO, is formed over the free layer.

In step 807, a reference layer is formed over the tunneling barrier layer. The reference layer, the tunneling barrier layer, and the free layer make up the MTJ. As described above, the reference layer may include a top reference layer, an RKKY spacer, and a bottom reference layer.

In step 809, a capping layer is formed over the reference layer. The capping layer may include Pt, Ru, Ir, Ta, CoFeB, CoFeBTa, TaB, TiN, or TaN. The capping layer may also include a combination of at least two of the above-mentioned materials that form a bilayer structure or a multilayered structure.

Alternatively, an insertion layer may be formed between the free layer and the tunneling barrier layer, e.g., as illustrated in FIG. 3B, or may be formed between seed layer and the free layer, e.g., as illustrated in FIG. 3C.

In accordance with the above-described embodiments, a free layer, i.e., an Mn—Sb compound material layer, is provided, which has PMA and low Mₛ, and therefore, is suitable for low-power MRAM products with PMA.

Additionally, Mn—Sb compounds are compatible with current state-of-the-art MTJ technology and more preferable for scaling.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

While the present disclosure has been shown and described with reference to certain embodiments thereof, it will be understood by those skilled in the art that various changes in form and details may be made therein without departing from the spirit and scope of the disclosure as defined by the appended claims and their equivalents.

What is claimed is:

1. A device, comprising:
a magnetic tunnel junction (MTJ) including a reference layer, a tunneling barrier layer, and a top free layer, wherein the tunneling barrier layer is formed on the reference layer, the top free layer is formed over the tunneling barrier layer, and the top free layer includes an Mn—Sb compound; and
a capping layer formed over the top free layer of the MTJ.

2. The device of claim 1, wherein the Mn—Sb compound includes Mn₃Sb.

3. The device of claim 1, wherein the Mn—Sb compound includes Mn₂Sb.

4. The device of claim 1, wherein the Mn—Sb compound includes MnₓSb, where x=1.5-3.

5. The device of claim 1, wherein the top free layer has a thickness of 0.5-10 nm.

6. The device of claim 1, wherein the tunneling barrier layer includes MgO.

7. The device of claim 1, wherein the tunneling barrier layer includes MgAl₂O₄.

8. The device of claim 1, wherein the tunneling barrier layer includes Mg_{1-z}Al_{2+(2/3)z}O₄, where −0.5<z<0.5).

9. The device of claim 1, wherein the capping layer includes at least one of MgO, Mg—Al-Ox, Zr-Ox, Hf-Ox, Al-Ox, Ta-Ox, Ca-Ox, Ta, Mo, W, Ru, CoFeB, TaB, TiN, TaN, ScN, or VN.

10. The device of claim 1, further comprising a seed layer formed below the reference layer of the MTJ.

11. The device of claim 10, wherein the seed layer includes at least one of Pt, Ru, Ir, Ta, CoFeB, CoFeBTa, TaB, TiN or TaN.

12. The device of claim 1, further comprising an insertion layer formed between the tunneling barrier layer and the top free layer, or between the top free layer and the capping layer.

13. The device of claim 12, wherein the insertion layer includes at least one of Co, Fe, Ni, Ta, Mo, W, Mn, a Co-containing alloy, an Fe-containing alloy, an Ni-containing alloy, or an Mn-containing alloy.

14. A device, comprising:
a magnetic tunnel junction (MTJ) including a reference layer, a tunneling barrier layer, and a bottom free layer, wherein the tunneling barrier layer is formed over the bottom free layer, the reference layer is formed on the tunneling barrier layer, and the bottom free layer includes an Mn—Sb compound; and
a capping layer formed over the reference layer of the MTJ.

15. The device of claim 14, wherein the Mn—Sb compound includes Mn₃Sb.

16. The device of claim 14, wherein the Mn—Sb compound includes Mn₂Sb.

17. The device of claim 14, wherein the Mn—Sb compound includes MnₓSb, where x=1.5-3.

18. The device of claim 14, wherein the bottom free layer has a thickness of 0.5-10 nm.

19. A method, comprising:
forming a magnetic tunnel junction (MTJ) including a reference layer, a tunneling barrier layer, and a free layer, wherein the free layer includes an Mn—Sb compound; and
forming a capping layer over the MTJ.

20. An electronic device, comprising:
a processor, and
a memory device including:
a magnetic tunnel junction (MTJ) including a reference layer, a tunneling barrier layer, and a free layer, wherein the free layer includes an Mn—Sb compound; and
a capping layer formed over the free layer of the MTJ.
